(19) United States
(12) Patent Application Publication
(10) Pub. No.: US 2011/0186131 A1
(43) Pub. Date: Aug. 4, 2011

(54) SUBSTRATE FOR SELENIUM COMPOUND SEMICONDUCTORS, PRODUCTION METHOD OF SUBSTRATE FOR SELENIUM COMPOUND SEMICONDUCTORS, AND THIN-FILM SOLAR CELL

(75) Inventors: Atsushi MUKAI, Ashigara-kami-gun (JP); Shigenori Yuya, Ashigara-kami-gun (JP); Toshiaki Fukunaga, Ashigara-kami-gun (JP); Ryuichi Nakayama, Ashigara-kami-gun (JP)

(73) Assignee: FUJIFILM Corporation, Tokyo (JP)

(21) Appl. No.: 13/016,095

(22) Filed: Jan. 28, 2011

(30) Foreign Application Priority Data
Jan. 29, 2010 (JP) 2010-017853
Jul. 29, 2010 (JP) 2010-170270

(51) Int. Cl. H01L 31/0272; C23C 8/10; C23C 8/80; C25D 11/02; B32B 15/04

(52) U.S. Cl. 136/264; 148/287; 148/241; 428/629

(57) ABSTRACT

A substrate for selenium compound semiconductor has at least a steel base and an aluminum base. The aluminum base is arranged on one end in a direction of lamination of the steel base and the aluminum base, the steel base is arranged on the other end in the direction. An alloy layer having a thickness of from 0.01 μm to 10 μm is formed between the steel base and the aluminum base. A thermal oxide film having a thickness of 6 nm or more is formed on a surface of the steel base opposite to the aluminum base.

### BACKGROUND OF THE INVENTION

The present invention relates to a substrate for selenium compound semiconductors in which selenium is used during production, a production method of a substrate for selenium compound semiconductors, and a thin-film solar cell. In particular, it relates to a substrate for selenium compound semiconductors and a production method thereof, wherein corrosion due to selenium used during production and contamination due to dust generated by disintegration of selenium compounds caused by corrosion by selenium can be suppressed, and a thin-film solar cell which uses this substrate for selenium compound semiconductors.

Recently, a great deal of research on solar cells has been conducted. Solar cell modules forming a solar cell each comprise a solar cell submodule including a number of series-connected laminate-structured photoelectric conversion elements formed on a substrate, each of which is essentially composed of a semiconductor photoelectric conversion layer generating current by light absorption sandwiched by an back electrode (bottom or lower electrode) and a transparent electrode (upper electrode). Presently, there remains an issue of reducing the costs of solar cell modules in the market of solar cell modules.

As the next generation of solar cell modules, those which use CIGS layers in the photoelectric conversion layers are being studied. Solar cell modules which use CIGS layers can be made from thin films because they have relatively high efficiency and high photoabsorptivity, and as a result, materials costs can be reduced. For this reason, they have been studied a great deal as a candidate for low-cost solar cell modules.

Also, as a substrate which constitutes a solar cell module, a substrate in which an alumina film is formed on top of the aluminum of a substrate made from a two-layer structure of stainless steel and aluminum has been proposed (refer to JP 2009-132996 A).

In JP 2009-132996 A, there is a metal substrate, with an intermediate layer and an insulation layer on top of that metal substrate. The intermediate layer is made from anodizable metal, and the insulation layer is made from anodized oxide of the metal that constitutes the intermediate layer.

The metal substrate is constructed, for example, from a stainless steel substrate, copper substrate, aluminum substrate, titanium substrate, iron substrate, iron alloy substrate or the like. The anodizable metal that constitutes the intermediate layer is, for example, aluminum, a group 4 transition elements (titanium, zirconium, hafnium) or a group 5 transition elements (vanadium, niobium, tantalum).

Since integration is possible using alumina in the insulation layer as in the heat-resistant insulating substrate disclosed in JP 2009-132996 A, production costs of the solar cell module can be reduced if this type of heat-resistant insulating substrate is used as the substrate. If the heat-resistant insulating substrate disclosed in JP 2009-132996 A is used as a thin-film substrate, it can be made flexible and a roll-to-roll process can be employed, and costs can thus be further decreased.

### SUMMARY OF THE INVENTION

However, when the substrate according to JP 2009-132996 A is used in a solar cell module, a back electrode is formed on the surface of the alumina of the substrate of JP 2009-132996 A, after which evaporated selenium (Se) is used in the process of forming the CIGS layers. This selenium vapor wraps around the back stainless steel side, and there is the problem that it corrodes the stainless steel. Due to this corrosion, there are also the problems that the strength of the substrate is reduced, iron-selenium compounds are formed, and powder of these iron-selenium compounds contaminates the processing chamber as dust. As a result, the quality of the formed CIGS layers decreases. Moreover, since the processing chamber is contaminated, productivity also ends up decreasing.

As a method for increasing corrosion resistance of stainless steel, a method by providing an oxide film having a principal component of silicon (Si) on ferritic stainless steel is known, as disclosed in JP 7-62520 A.

In JP 7-62520 A, a stainless steel material for clean rooms is disclosed, which has an oxide film having a principal component of silicon on the surface of austenite stainless steel material containing 0.5-5.0 wt % silicon.

Also, in JP 7-62520 A, a stainless steel material for clean rooms is produced by heating austenite stainless steel containing 0.5-5.0 wt % silicon in the temperature range of 750-1200° C. in an inert gas atmosphere or hydrogen atmosphere having an oxygen concentration of 10 ppm or less by volume and having a water vapor concentration of 10 ppm or less by volume. For this reason, when using a substrate wherein an anodized film is provided on a two-layer structure substrate of stainless steel and aluminum, there are the problems that cracks occur in the anodized film and it loses its function as an insulation layer, and that it must be heated to above the melting point of aluminum, and therefore the method of JP 7-62520 A is impractical.

Thus, the current situation is such that when selenium is used in the production process, corrosion of the back of the substrate cannot be suppressed, and high-quality CIGS layers cannot be stably produced.

An objective of the present invention is to resolve the problems based on the aforementioned prior art, and to provide a substrate for selenium compound semiconductors that can suppress corrosion by selenium and contamination by dust generated by disintegration of selenium compounds occurring due to corrosion by selenium, and a production method of a substrate for selenium compound semiconductors, and a thin-film solar cell which uses this substrate for selenium compound semiconductors.

Another objective of the present invention is to provide a substrate for selenium compound semiconductors having good insulation characteristics, mechanical strength and flexibility even after being exposed to high temperature when selenium is evaporated and the photoelectric conversion layer is formed, and a production method of a substrate for selenium compound semiconductors, and a thin-film solar cell which uses this substrate for selenium compound semiconductors.

To achieve the above objectives, a first aspect of the present invention provides a substrate for selenium compound semiconductor, comprising: at least a steel base; and an aluminum base, wherein the aluminum base is arranged on one end in a direction of lamination of the steel base and the aluminum base, the steel base is arranged on the other end in the direction of lamination, and wherein an alloy layer having a thickness of from 0.01 μm to 10 μm is formed between the steel base and the aluminum base, and wherein a thermal oxide film having a thickness of 6 nm or more is formed on a surface of the steel base opposite to the aluminum base.

It is preferred that an insulation layer made of alumina is formed on a surface of the aluminum base opposite to the steel base.

It is preferred that the insulation layer comprises an anodized film formed by anodizing a material of the aluminum base made of aluminum.

It is preferred that the steel base, the aluminum base, the thermal oxide film and the insulation layer are flexible.

It is preferred that the thermal oxide film contains Fe₂O₃, Fe₃O₄ and Cr₂O₃.

It is preferred that the thermal oxide film is an iron-based oxide film containing Fe₃O₄ as a principal component.

In addition, It is preferred that the thermal oxide film has a thickness of at least 25 nm.

Also, the alloy layer has a principal component of alloy having the composition expressed by Al₃X (X is Fe or Cr).

Also, a second aspect of the present invention provides a production method of a substrate for selenium compound semiconductor on which treatment using selenium is performed, comprising the steps of: forming a substrate body in which at least a steel base and an aluminum base are laminated such that the aluminum base is arranged on one end in a direction of lamination and the steel base is arranged on the other end in the direction of lamination; and, performing thermal oxidation treatment on the substrate body to form a thermal oxide film having a thickness of 6 nm or more on a surface of the steel base opposite to the aluminum base, as well as to form an alloy layer having a thickness of from 0.01 μm to 10 μm between the steel base and the aluminum base.

It is preferred that further comprising a step of forming an insulation layer made of alumina on the surface of the aluminum base opposite to the steel base.

It is preferred that the thermal oxidation treatment is performed after the step of forming the insulation layer and before the treatment using selenium.

It is preferred that the insulation layer is formed by anodization treatment.

It is preferred that the thermal oxide film is formed at a temperature of from 150° C. to 600° C.

It is preferred that the thermal oxide film is formed in an atmosphere containing oxygen, an atmosphere containing carbon dioxide gas, or an atmosphere containing water vapor.

In addition, It is preferred that the steel base comprises ferritic stainless steel or austenitic stainless steel.

A third aspect of the present invention provides A thin-film solar cell, comprising: the substrate for selenium compound semiconductor according to claim 1; and photoelectric conversion layers formed on the substrate, wherein the photoelectric conversion layers are selenium compound semiconductor formed by evaporating at least selenium.

A fourth aspect of the present invention provides A thin-film solar cell, comprising: the substrate for selenium compound semiconductor according to claim 2; and films laminated on the insulation layer of the substrate and constituting the selenium compound semiconductor, wherein the films comprises: at least a back electrode made of molybdenum and formed on the insulation layer of the substrate; and a photoelectric conversion layer made of CIGS and formed on the back electrode.

It is preferred that at least the back electrode is formed by using a roll-to-roll process.

It is preferred that an integrated device comprises said back electrode formed in a predetermined pattern and said photoelectric conversion layer formed in a predetermined pattern.

It is preferred that further comprising a soda lime glass layer formed between said insulation layer of said substrate and said back electrode.

According to the present invention, by providing a thermal oxide film which tends not to react with selenium vapor on the steel base, direct contact between selenium vapor and the steel base is prevented, reaction between the steel base and selenium vapor is prevented, and corrosion is prevented. As a result, corrosion due to selenium does not occur, and therefore the strength of the substrate can be maintained, and iron-selenium compounds formed by reaction between selenium and the steel base are not produced. For this reason, iron-selenium compounds and so forth do not turn into dust, and do not contaminate the processing chamber. For these reasons, good CIGS layers can be stably formed in the case where the substrate of the present invention is used as the substrate of thin-film solar cells wherein CIGS layers are formed as the photoelectric conversion layers (photoabsorption layers). Moreover, since the processing chamber is not contaminated by dust, productivity does not decrease.

According to the present invention, in the case where an anodized film was used as the insulation layer, a thermal oxide film is formed by thermal oxidation treatment, and therefore, moisture adsorbed to the surface of the anodized film during storage of the substrate or moisture contained inside the anodized film can be minimized. For this reason, the degree of vacuum inside the processing chamber does not deteriorate in the vacuum deposition processes when forming the CIGS layers and so forth, and throughput can be improved.

Also, according to the present invention, by setting the thickness of the alloy layer to 0.01-10 μm, interface adhesion in the substrate can be appropriately assured, and in addition, the occurrence of interface peeling and substrate curling can be appropriately suppressed even when voids and so forth arising in the alloy layer are generated. The resultant reduction in insulation performance can be inhibited. In particular, by setting the alloy layer thickness to 0.01-5 μm, the generation of voids and so forth can be more appropriately suppressed, and the occurrence of interface peeling and substrate curling can be more reliably suppressed.

### BRIEF DESCRIPTION OF THE DRAWINGS

FIG. 1 is a cross-sectional diagram schematically illustrating a substrate for selenium compound semiconductors according to a first embodiment of the present invention.

FIG. 2A schematically illustrates the heat treatment conditions that result in an intermetallic compound thickness of 10 μm in the substrate body in which an aluminum base is provided on a steel base, and FIG. 2B schematically illustrates the heat treatment conditions that result in an intermetallic compound thickness of 5 μm.

FIG. 3 is a graph illustrating the time dependence of oxide film thickness at a heating temperature of 450° C.

FIG. 4 is a graph illustrating the heating temperature dependence of oxide film thickness.

FIGS. 5A-5D are cross-sectional diagrams schematically illustrating, in order of the steps, the production method of the substrate for selenium compound semiconductors according to the first embodiment of the present invention.

FIG. 6 is a cross-sectional diagram schematically illustrating a solar cell submodule provided in a thin-film solar cell module according to a second embodiment of the present invention.

FIG. 7A is a photograph showing the back of the substrate of experimental example No. 1, and FIG. 7B is a photograph showing an enlargement of the back of the substrate of experimental example No. 1.

FIG. 8A is a photograph showing the back of the substrate of experimental example No. 10, and FIG. 8B is a photograph showing an enlargement of the back of the substrate of experimental example No. 10.

FIG. 9 is a graph illustrating the tolerable thickness of the oxide film in sample A.

FIG. 10 is a graph illustrating the tolerable thickness of the oxide film in sample B.

### DETAILED DESCRIPTION OF THE INVENTION

The substrate for selenium compound semiconductors, the production method of the substrate for selenium compound semiconductors, and the thin-film solar cell of the present invention will be described below based on preferred embodiments illustrated in the attached drawings.

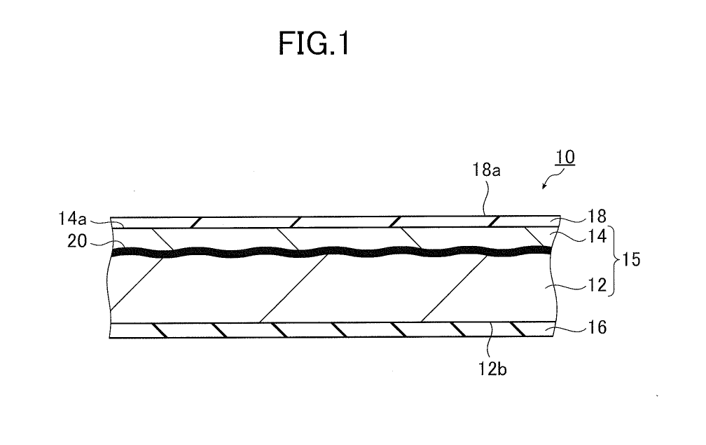

FIG. 1 is a cross-sectional diagram schematically illustrating a first embodiment of the substrate for selenium compound semiconductors according to the present invention.

As shown in FIG. 1, the substrate for selenium compound semiconductors 10 (referred to simply as “substrate 10” hereinafter) has a steel base 12, an aluminum base 14, an oxide film 16, an insulation layer 18 and an alloy layer 20.

In the substrate 10, the aluminum base 14 is formed on the front surface 12a of the steel base 12, and the oxide film 16 is formed on the back surface 12b of the steel base 12. The insulation layer 18 is formed on the front surface 14a of the aluminum base 14. The alloy layer 20 is produced at the interface between the steel base 12 and aluminum base 14. The laminate consisting of the steel base 12 and the aluminum base 14 is also called the substrate body 15.

Note that in the present invention, the substrate 10 also includes the case where an insulation layer 18 is not provided on the substrate 10, the aluminum base 14 is formed on the front surface 12a of the steel base 12, and the oxide film 16 is formed on the back surface 12b of the steel base 12.

The substrate 10 of this embodiment is utilized as the substrate of semiconductor elements, solar cell modules or the like comprising a selenium compound semiconductor produced using selenium in the production process. For this reason, the substrate 10 has the form of a flat sheet, for example, and the shape and size of the substrate 10 are appropriately determined according to the scale of production of the semiconductor elements or the size of the solar cell modules in which it is used, etc.

In the substrate 10, mild steel, heat-resistant steel, austenitic stainless steel or ferritic stainless steel may be used in the steel base 12.

The steel base 12 has higher heat-resistant strength at 300° C. or above than aluminum alloys, and a certain heat resistance of the substrate 10 is thereby obtained.

As mild steel, a low-carbon steel such as SS400 or the like may be used.

As austenitic stainless steel, SUS304, SUS316, SUS310, SUS309, SUS317, SUS321, SUS347 or the like may be used.

Also, as ferritic stainless steel, SUS430, SUS405, SUS410, SUS436, SUS444 or the like may be used.

Other than the above, SPCC steel or martensitic stainless steel such as SUS403, SUS440, SUS420 and SUS410 may also be used.

The thickness of the steel base 12 affects flexibility, and is preferably thin, but in a range such that it does not excessively lack hardness.

In the substrate 10 of this embodiment, the thickness of the steel base 12 is, for example, 10-800 μm, preferably 30-300 μm. It is more preferably 50-150 μm. Reducing the thickness of the steel base 12 is also preferred from the viewpoint of raw materials costs.

For a flexible steel base 12, the steel base 12 is preferably austenitic stainless steel or ferritic stainless steel. For a steel base 12 that has particularly high heat-resistant strength, austenitic stainless steel is preferred. SUS304 and SUS316 are general-purpose steels as austenitic stainless steel, but to obtain a steel base 12 that has particularly high heat resistance, SUS310 and SUS309 are preferred.

The aluminum base 14 is constructed with a principal component of aluminum. Having aluminum as the principal component means an aluminum content of 90 mass % or more.

As the aluminum base 14, aluminum or aluminum alloy, for example, may be used. The aluminum or aluminum alloy preferably does not contain extraneous intermetallic compounds. Specifically, aluminum with a purity of at least 99 mass % which contains few impurities is preferred. For example, aluminum with a purity of 99.99 mass %, aluminum with a purity of 99.96 mass %, aluminum with a purity of 99.9 mass %, aluminum with a purity of 99.85 mass %, aluminum with a purity of 99.7 mass % and aluminum with a purity of 99.5 mass % are preferred. Also, aluminum alloys to which elements that tend not to form intermetallic compounds have been added may be used. An example is aluminum alloy to which 2.0-7.0 mass % magnesium has been added to 99.9 mass % aluminum. Other than magnesium, elements with a high solid solubility limit, such as copper or silicon, may be added.

In cases where an insulation layer 18 is provided, it is preferred that the aluminum purity of the aluminum base 14 is increased. By so doing, it is possible to avoid intermetallic compounds caused by precipitates and to increase the soundness of the insulation layer 18. This is because when anodization of the aluminum alloy is performed, there is a possibility of poor insulation originating from intermetallic compounds, and if there are a lot of intermetallic compounds, this possibility increases.

Also, the thickness of the aluminum base 14 is, for example, 5-150 μm, preferably 10-100 μm. It is more preferably 20-50 μm.

Also, the surface roughness of the aluminum base 14 is, for example, 1 μm or less as arithmetic mean roughness Ra. It is preferably 0.5 μm or less, more preferably 0.1 μm or less.

Note that the front surface of the aluminum base 14 may be mirror-finished. This mirror finishing may be performed according to the methods stated in JP 4212641 B, JP 2003-341696 A, JP 7-331379 A, JP 2007-196250 A or JP 2000-223205 A.

The oxide film 16 may be one formed by natural oxidation, but it may also be a thermal oxide film formed on the back surface 12b of the steel base 12 of the substrate body 15 by thermally oxidizing the steel base 12. This oxide film 16 tends not to react with selenium, and it is provided in order to prevent direct contact between the steel base 12 and selenium. This oxide film 16 prevents reaction between the steel base 12 and selenium, and therefore prevents corrosion of the steel base 12 by selenium. Thus, due to the oxide film 16, the strength of the substrate 10 can be maintained because corrosion by selenium does not occur.

The oxide film 16 contains, for example, Fe₂O₃, Fe₃O₄ and Cr₂O₃. Also, the oxide film 16 may be an iron-based oxide film having a principal component of Fe₃O₄. Since the oxide film 16 is formed by thermal oxidation of the steel base 12, its composition depends on the composition of the steel base 12. Also, the thickness of the oxide film 16 is, for example, 6 nm or more. It is preferred that the thickness of the oxide film 16 is at least 25 nm. Furthermore, it is preferred that the thickness of the oxide film 16 is less than 100 nm.

The thickness of the oxide film 16 can be determined as follows. First, using Auger electron spectroscopy, the molar concentration (%) of oxygen is measured in the direction of depth from the front surface of the oxide film 16 toward the steel base 12. Then, based on the oxygen molar concentration (%) measurement results, the distance in the direction of depth until the oxygen molar concentration (%) of the front surface of the oxygen film 16 drops by half is determined, and this distance is taken as the thickness of the oxide film 16.

In the substrate 10, the insulation layer 18 is for insulation and for preventing damage by mechanical impact during handling. The insulation layer 18 is constructed from an anodized film, for example. When the aluminum base 14 is aluminum or aluminum alloy, the insulation layer 18 is aluminum anodized film (alumina film).

The insulation layer 18 is not limited to an anodized film, and may be formed by vapor deposition, sputtering or CVD.

The insulation layer 18 preferably has a thickness of at least 5 μm, more preferably at least 10 μm. An excessively thick insulation layer 18 is not preferred because flexibility is reduced and cost is increase and manufacturing time is increase for forming the insulation layer 18. In practice, the thickness of the insulation layer 18 is up to 50 μm, preferably up to 30 μm. Therefore, the preferred thickness of the insulation layer 18 is from 0.5 to 50 μm.

The front surface 18a of the insulation layer 18 has a surface roughness in terms of, for example, arithmetic mean roughness Ra, of 1 μm or less, preferably 0.5 μm or less, and more preferably 0.1 μm or less.

The tensile strength of the substrate 10 when heat treated at 500° C. or above must be at least 5 MPa, and is preferably at least 10 MPa.

Also, in order that creep deformation does not occur during heat treatment at 500° C. or above, it is preferred that the force that causes a maximum of 0.1% plastic deformation when held for 10 minutes at 500° C. is at least 0.2 MPa, more preferably at least 0.4 MPa, even more preferably at least 1 MPa.

Note that the substrate 10 includes the steel base 12, the aluminum base 14, the oxide layer 16 and the insulation layer 18, all of which are made of flexible materials, and therefore, the substrate 10 is flexible as a whole. Thus, on the insulation layer 18 side of the substrate 10, selenium compound semiconductors or the like which use selenium may be formed by the roll-to-roll process, for example.

In the substrate 10, the alloy layer 20 produced at the interface between the steel base 12 and the aluminum base 14 is an aluminum alloy corresponding to the type of steel base 12, and is assumed to be a layer made up primarily of an intermetallic compound (IMC). Specifically, if the steel base 12 is iron, the alloy layer 20 is assumed to be Al₃Fe, and if the steel base 12 is alloy steel, the alloy layer 20 is assumed to be a layer in which an alloy element such as Cr, for example, has gone into solid solution at the Fe sites of Al₃Fe.

Here, the aluminum base 14 diminishes due to the generation (growth) of the alloy layer 20, but the steel base 12 undergoes almost no diminishment.

If there is no alloy layer 20 present at all, the interface adhesion between the steel base 12 and the aluminum base 14 is poor, and when thermal cycling or bending stress is applied during the roll-to-roll production process or during use of the solar cells or semiconductor devices, interface peeling occurs between the steel base 12 and the aluminum base 14, causing peeling or cracking of the insulation layer.

Conversely, if the alloy layer 20 is too thick, the intermetallic compound that primarily forms the alloy layer 20 is brittle, and as the thick alloy layer 20 is formed, voids and cracks occur between the alloy layer 20 and the aluminum base 14, and this causes interface peeling and loss of insulation function.

According to studies by the inventors, the thickness of the alloy layer 20 must be 0.01-10 μm, more preferably 5 μm or less, in order to avoid the problems described above and to suitably realize the effect of having an alloy layer 20.

Note that the thickness of the alloy layer 20 may be the thickness at the time when the substrate 10 has been completed, or it may be the thickness at the time when the semiconductor devices such as the solar cell submodules 30 described below have been completed.

By setting the thickness of the alloy layer 20 to 0.01-10 μm, interface adhesion can be appropriately assured due to the fact that there is an alloy layer 20, and in addition, insulation characteristics can be suitably assured and the occurrence of interface peeling and substrate curling can be appropriately suppressed, even when voids and so forth arising in the alloy layer 20 are generated. In particular, by setting the thickness of the alloy layer 20 to 0.01-5 μm, the generation of voids and so forth can be more appropriately suppressed, the occurrence of interface peeling and substrate curling can be more reliably suppressed, and the decrease in insulation performance caused by them can be suppressed.

Note that if the alloy layer 20 is thin, it is often the case that the alloy layer 20 is generated in the form of islands at the interface between the steel base 12 and the aluminum base 14. Even with this type island-form alloy layer 20, the effect of having the alloy layer 20 is suitably realized.

Note that in the present invention, the thickness of the alloy layer 20 means the average thickness of a cross-section of the substrate 12 (insulating metal substrate). Also, the average thickness of the cross-section of the substrate 12 may be measured by observing the cross-section of the substrate 12.

Specifically, the thickness of the alloy layer 20 is determined by slicing the substrate 12 (semiconductor device such as a solar cell submodule 30) to reveal the cross-section of the substrate 12, and then photographing this cross-section by SEM (scanning electron microscope) or the like, measuring the area of the alloy layer 20 in the photograph by image analysis, and dividing by the length of the field of observation.
As described above, if the alloy layer 20 is thin, the alloy layer 20 is generated in the form of islands at the interface between the steel base 12 and the aluminum base 14. Even in this case, the thickness of the alloy layer 20 may be taken as the average thickness as described above, rather than the thickness of each island.

The thickness of the alloy layer 20 is not uniform, and the alloy layer 20 has some asperities. However, although the some asperities can be seen, the alloy layer 20 normally grows approximately uniformly. Growth in faceted shapes, growth in whisker shapes and abnormal growth that greatly eats into the steel base 12 or aluminum base 14 do not occur. Therefore, the thickness of the alloy layer 20 can be accurately measured by the above measurement method using a photographed image.

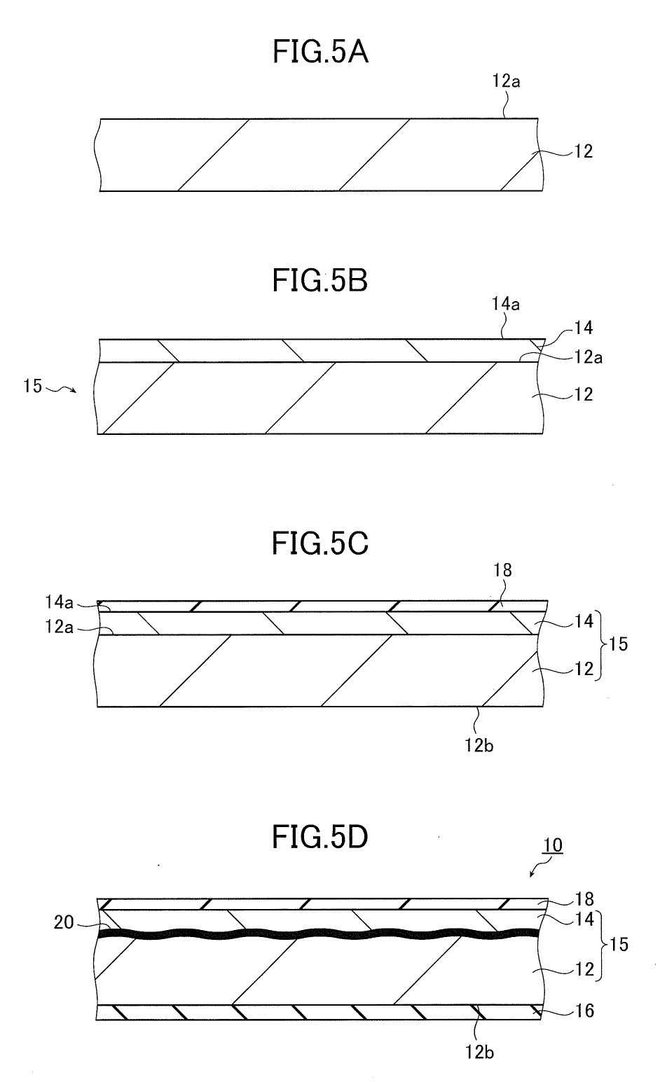

As the method of forming the alloy layer 20, for example, a substrate body 15 having a steel base 12, aluminum base 14 and insulation layer 16 as shown in FIG. 5D described below is produced, and then the alloy layer 20 is formed by thermal oxidation treatment.

The thickness of the alloy layer 20 differs depending on the reactivity between aluminum and the material of the steel base 12, but it is basically determined by the thermal history (temperature and time) undergone by the substrate 10.

Therefore, the heat treatment conditions (holding temperature and holding time=thermal history) that will result in the desired thickness of the alloy layer 20 in the range of 0.01-10 μm (preferably 0.01-5 μm) is examined in advance either experimentally or by simulation in accordance with the combination of substrate 12 and aluminum base 14, and as a result, thermal oxidation treatment of the substrate body 15 as described above can be performed accordingly. Also, in cases where there is a high-temperature process such as a photoelectric conversion layer film deposition process in the production process of the semiconductor devices such as the solar cell submodule described below, the treatment conditions in the high-temperature process can be set such that the alloy layer 20 has the desired thickness.

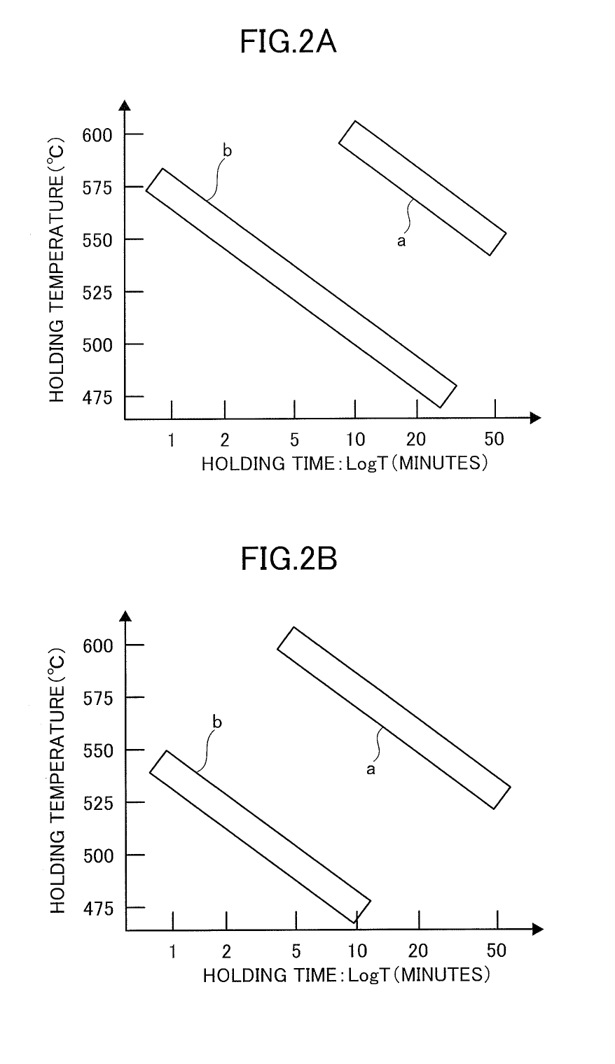

FIG. 2A illustrates the heat treatment conditions that result in an alloy layer 20 of thickness 10 μm generated at the interface between the steel base 12 and aluminum base 14, in the format of a TTT (time temperature transformation) diagram.

In the example shown in FIG. 2A, the aluminum base 14 is high-purity aluminum of purity 4N. In the diagram, a indicates an example where the steel base 12 is ferritic stainless steel (SUS430), and b indicates an example where the steel base 12 is low-carbon steel (SPCC).

As shown in FIG. 2A, the heat treatment conditions that result in an alloy layer 20 of thickness 10 μm are such that the higher the holding temperature, the shorter the time, or the longer the holding time, the lower the temperature.

If the steel base 12 is low-carbon steel, when the holding temperature is 500° C., for example, the thickness of the alloy layer 20 is 10 μm with a holding time of about 10 minutes, as indicated by b in FIG. 2A. Therefore, in the production process of a semiconductor device such as the solar cell submodule 30 described below, if treatment is performed at 500° C., the thickness of the alloy layer 20 will be 10 μm or less if the treatment time is 10 minutes or less. Conversely, if treatment is performed for 10 minutes, the thickness of the alloy layer 20 will be 10 μm or less if the treatment temperature is 500° C. or less.

Also, if the steel base 12 is low-carbon steel, when the holding temperature is 525° C., the thickness of the alloy layer 20 is 10 μm with a holding time of about 5 minutes. Therefore, in the production process of semiconductor devices such as a solar cell submodule 30, if treatment is performed at 525° C., the thickness of the alloy layer 20 will be 10 μm or less if the treatment time is 5 minutes or less. Conversely, if treatment is performed for 5 minutes, the thickness of the alloy layer 20 will be 10 μm or less if the treatment temperature is 525° C. or less.

In other words, in the present invention, when treatment is performed at 500° C. in the production process, low-carbon steel can be used as the steel base 12 if the treatment time is 10 minutes or less, and when treatment is performed for 10 minutes, low-carbon steel can be used as the steel base 12 if the treatment temperature is 500° C. or less.

Also, when treatment is performed at 525° C. in the production process, low-carbon steel can be used as the steel base 12 if the treatment time is 5 minutes or less, and when treatment is performed for 5 minutes, low-carbon steel can be used as the steel base 12 if the treatment temperature is 525° C. or less.

If the steel base 12 is ferritic stainless steel, as indicated by a in FIG. 2A, the heat treatment conditions that result in an alloy layer 20 thickness of 10 μm become a higher temperature and longer time.

If the steel base 12 is ferritic stainless steel, if the holding temperature is 575° C., for example, an alloy layer 20 of thickness 10 μm will be produced with a holding time of 20 minutes. That is, if a solar cell submodule 30 or the like is produced using ferritic stainless steel as the steel base 12, treatment up to 20 minutes is possible when treatment is at 575° C., and conversely, high-temperature treatment up to 575° C. is possible when treatment is performed for 20 minutes.

In other words, when treatment is performed at 575° C., ferritic stainless steel can be used as the steel base 12 if the treatment time is 20 minutes or less, and when treatment is performed for 20 minutes, ferritic stainless steel can be used as the steel base 12 if the treatment temperature is 575° C. or less.

FIG. 2B shows the heat treatment conditions that result in an alloy layer 20 of thickness 5 μm in the same aluminum base 14 and steel base 12. Note that in the diagram, a and b are the same as in FIG. 2A.

As shown in FIG. 2B, the heat treatment conditions that result in an alloy layer 20 of thickness 5 μm are a lower temperature and shorter time than for a thickness of 10 μm.

However, as shown b of in FIG. 2B, even if low-carbon steel is used as the steel base 12, when the treatment temperature is 500° C., the thickness of the alloy layer 20 is 5 μm or less if the treatment time is 5 minutes or less. That is, when treatment is performed at 500° C., low-carbon steel can be used as the steel base 12 if the treatment time is 5 minutes or less, and when treatment is performed for 5 minutes, low-carbon steel can be used as the steel base 12 if the treatment temperature is 500° C. or less.

Also, as shown in a of FIG. 2B, if ferritic stainless steel is used as the steel base 12, treatment can be performed for 20 minutes at 550° C., for example, even when the desired thickness of the alloy layer 20 is 5 μm or less.

That is, when using a steel base 12, under the heat treatment conditions (thermal history) shown in FIGS. 2A and 2B, the thickness of the alloy layer 20 of the substrate 10 can be 10 μm or less, provided that the heat treatment conditions are in the region below and/or to the left of the region that results in the thickness of the alloy layer 20 being 10 μm or 5 μm. Therefore, in the production process of solar cells or the like that employ a substrate 10 having a steel base 12, treatment can be performed under conditions in the region below and/or to the left of the region that results in an alloy layer 20 thickness of 10 μm, and formation of photoelectric conversion layers can be performed at 500° C. or above, for example, by selecting the base materials and the film deposition conditions.

Note that the reason that the region that results in the thickness of the alloy layer 20 being 10 μm and 5 μm has a band shape is that, as described above, the thickness of the alloy layer 20 is not uniform, and the alloy layer 20 has asperities.

Therefore, basically, if the heat treatment conditions are in the region below and/or to the left of the upper line of the band that results in thickness of 10 μm, the thickness of the alloy layer 20 can be 10 μm or less. Additionally, in cases where it is desired to more reliably ensure that the thickness of the alloy layer 20 is 10 μm or less, it is preferred that the heat treatment conditions are in the region below and/or to the left of the lower line of the band that results in thickness of 10 μm.

In the production process of semiconductor devices such as the solar cell submodule 30, if the substrate 10 suffer high temperature multiple times, since it can be thought that the rule of addition (additivity rule), the thickness of the alloy layer 20 can be set to 10 μm or 5 μm or less by adding the temperature and the treatment time of each heat treatment such as thermal oxidation treatment.

In the present invention, in the substrate body 15 in which the aluminum base 14 and the steel base 12 are laminated, it was attempted to form a thermal oxide film as the oxide film 16 on the steel base 12, but it was discovered that when the alloy layer 20 is formed at the interface between the aluminum base 14 and the steel base 12 in the thermal oxidation treatment process, there is the problem that interface strength is low and peeling occurs in the alloy layer 20 if the temperature of the thermal oxidation treatment process is high or the heating time is long. As a result, it was discovered that there are optimum conditions for the thermal oxidation treatment process, and therefore there is an optimum range of structures.

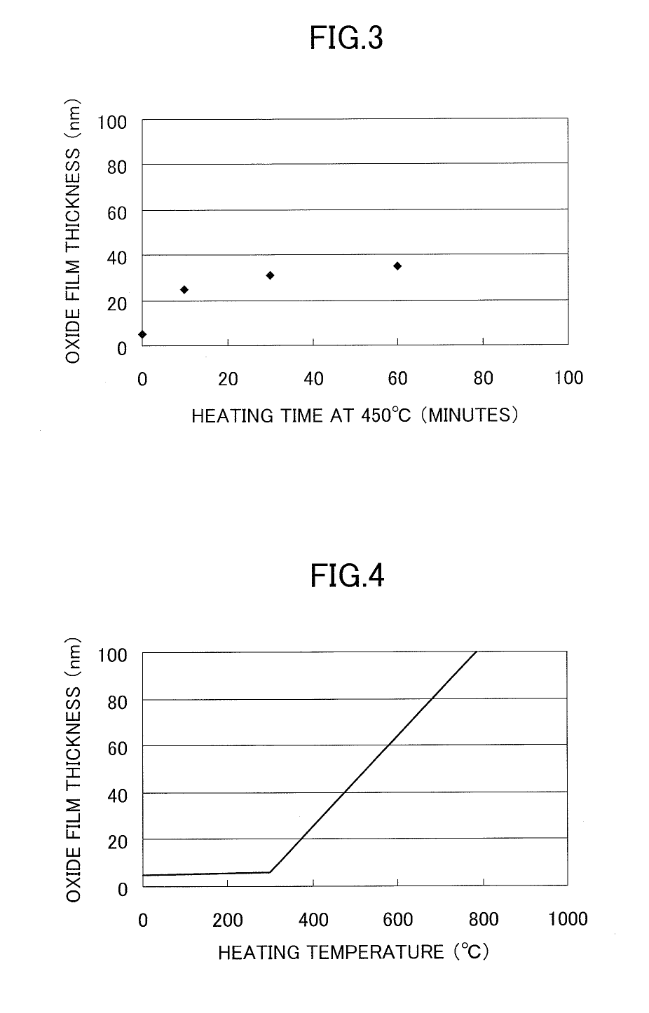

For the substrate body 15 in which an aluminum base 14 and steel base 12 were joined, thermal oxidation was performed at 450° C. under theoretical air flow while varying the time, and the oxide film thickness was measured by depth-resolved Auger electron spectroscopy. The results are shown in FIG. 3. As shown in FIG. 3, oxide film thickness had a saturated slope versus time, and the thickness of the oxide film obtained with thermal oxidation treatment for 1 hour was 35 nm.

Also, FIG. 4 shows the results of oxide film thickness in the case where thermal oxidation treatment was performed for 1 hour under theoretical air flow while varying the thermal oxidation treatment temperature. As shown in FIG. 4, it is effective to raise the thermal oxidation treatment temperature to obtain an oxide film thickness of 35 nm or above. Note that theoretical air flow is gas flow in which the ratio of N₂ gas:O₂ gas is 4:1 (N₂ gas:O₂ gas=4:1).

Also, the substrate 10 of this embodiment is configured so as to have a substrate body 15 having a two-layer structure of a steel base 12 and an aluminum base 14, but the present invention is not limited thereto. The substrate 10 is not limited to a two-layer structure of a steel base 12 and an aluminum base 14, provided that a steel base 12 and an aluminum base 14 are the outermost layers in the state where the oxide film 16 and the insulation layer 18 have been removed, that is, provided that it is laminated such that a steel base 12 is arranged on one end in the direction of lamination and an aluminum base 14 is arranged on the other end. In the substrate body 15, there may also be one or a plurality of bases made from other metals or alloys between the steel base 12 and the aluminum base 14.

Next, the production method of the substrate 10 of this embodiment will be described.

FIGS. 5A-5D are cross-sectional diagrams schematically illustrating, in order of the steps, the production method of the substrate for selenium compound semiconductors according to the first embodiment of the present invention.

First, as shown in FIG. 5A, the steel base 12 is prepared. The steel base 12 has a predetermined shape and size appropriate for the size of the substrate 10 to be formed.

Next, as shown in FIG. 5B, the aluminum base 14 is formed on the front surface 12a of the steel base 12. The substrate body 15 is thus formed.

The method of forming the aluminum layer 14 on the front surface 12a of the steel base 12 is not particularly limited, provided that an integral bond that can assure adhesion between the steel base 12 and the aluminum base 14 is achieved. As the formation method of the aluminum base 14, for example, vapor-phase methods such as vapor deposition or sputtering, plating, and pressurizing and bonding after surface cleaning may be used. Pressure-bonding by rolling or the like is the preferred method of forming the aluminum base 14 in terms of cost and mass producibility.

Next, as shown in FIG. 5C, the insulation layer 18 is formed on the front surface 14a of the aluminum base 14 of the substrate body 15. The insulation layer 18 is constructed from an anodized film, for example.

When an anodized film is formed as the insulation layer 18, it can be formed by immersing the steel base 12 as the anode in an electrolytic solution together with a cathode, and applying voltage between the anode and the cathode. In this case, the steel base 12 forms a local cell with the aluminum base 14 upon contact with the electrolytic solution, and therefore the steel base 12 which contacts the electrolytic solution must be insulated by masking with a protective sheet (not shown). That is, the end surfaces and back surface 12b of the steel base 12 other than the front surface 14a of the aluminum base 14 must be insulated using a protective sheet (not shown).

Where necessary, the front surface 14a of the aluminum base 14 may be subjected to cleaning and polishing/smoothing processes prior to anodization.

Carbon or aluminum or the like is used for the cathode in anodization. As the electrolyte, an acidic electrolytic solution containing one or more kinds of acids such as sulfuric acid, phosphoric acid, chromic acid, oxalic acid, sulfamic acid, benzenesulfonic acid and amidosulfonic acid is used. The anodization conditions vary with the type of electrolyte used and are not particularly limited. As an example, appropriate anodization conditions are an electrolyte concentration of 1-80 mass %, a solution temperature of 5-70° C., a current density of 0.005-0.60 A/cm², a voltage of 1-200 V and an electrolysis time of 3-500 minutes. The electrolyte is preferably sulfuric acid, phosphoric acid, oxalic acid or a mixture thereof. When an electrolyte as described above is used, an electrolyte concentration of 4-30 mass %, a solution temperature of 10-30° C., a current density of 0.002-0.30 A/cm² and a voltage of 20-100 V are preferred.

When anodization treatment is performed, an oxidation reaction proceeds substantially in the vertical direction from the front surface 14a of the aluminum base 14 to form an anodized film on the front surface 14a of the aluminum base 14. In cases where any of the above electrolytic solutions is used, the anodized film is of a porous type in which a large number of fine columns in the shape of a substantially regular hexagon as seen from above are arranged without gaps, and a micropore having a rounded bottom is formed at the core of each fine column, the bottom of each fine column having a barrier layer (typically 0.02-0.1 μm thick).

Compared to non-porous-structure aluminum oxide single film, this type of porous-structure anodized film has a lower Young's modulus, higher bending resistance, and higher resistance to cracking due to a difference in thermal expansion when heated.

Note that a dense anodized film (non-porous aluminum oxide single film), rather than an anodized film in which porous fine columns are arranged, is obtained by electrolytic treatment in a neutral electrolytic solution such as boric acid without using an acidic electrolytic solution. An anodized film in which the thickness of the barrier layer has been increased by pore filling may be formed by again performing electrolysis treatment with a neutral electrolytic solution after the porous anodized film is produced with an acidic electrolytic solution. The insulation properties of the film may be increased by increasing the thickness of the barrier layer.

The electrolytic solution used in the anodization treatment is preferably sulfuric acid aqueous solution or oxalic acid aqueous solution. Oxalic acid aqueous solution is excellent for soundness of the anodized film, and sulfuric acid aqueous solution is excellent for mass producibility by a continuous process.

As described above, the anodized film serving as the insulation layer 18 preferably has a thickness of 0.5-50 μm. The thickness can be controlled by the electrolysis time and the magnitudes of the current and voltage in constant current electrolysis or constant voltage electrolysis.

In cases where it is desired to increase the insulation properties of the insulation layer 18 formed by anodization, pore sealing treatment is performed in a boric acid solution.

Electrochemical methods and chemical methods of pore sealing are known, but an electrochemical method wherein aluminum and aluminum alloy are anodized (anodic treatment) is particularly preferred.

A preferred electrochemical pore sealing method is that in which DC current is applied to aluminum or an alloy thereof as the anode. Boric acid aqueous solution is preferred as the electrolytic solution, and an aqueous solution obtained by adding a borate containing sodium to boric acid aqueous solution is even more preferred. Examples of borates include disodium octaborate, sodium tetraphenylborate, sodium tetrafluoroborate, sodium peroxoborate, sodium tetraborate, sodium metaborate and so forth. The borates may be procured as anhydrides or hydrates.

A particularly preferred electrolytic solution used in pore sealing is an aqueous solution obtained by adding 0.01-0.5 mol/L sodium tetraborate to 0.1-2 mol/L boric acid aqueous solution. It is preferred that aluminum ions are dissolved in an amount of 0-0.1 mol/L. Aluminum ions may be dissolved chemically or electrochemically by pore sealing treatment in an electrolytic solution, but a particularly preferred method is electrolysis after adding aluminum borate in advance. Also, trace elements contained in the aluminum alloy may be dissolved.

Preferred pore sealing conditions are a solution temperature of 10-55° C. (more preferably 10-30° C.), a current density of 0.01-5 A/dm² (more preferably 0.1-3 A/dm²) and an electrolytic treatment time of 0.1-10 minutes (more preferably 1-5 minutes).

The current used may be AC, DC or overlapping AC current, and the method of applying current may be by constant application from the start of electrolysis or by gradual increase, but the use of DC is particularly preferred. The method of applying current may be either by constant voltage or constant current.

The voltage between the substrate and the opposing electrode in this case is preferably 100-1000 V, but varies depending on the composition of the electrolytic solution, solution temperature, flow rate at the aluminum interface, power supply waveform, distance between substrate and opposing electrode, electrolysis time and so forth.

The flow and the method of providing flow of the electrolytic solution on the substrate surface and the method of concentration control of the electrolyte tank, electrodes and electrolytic solution may be known methods of anodization treatment and pore sealing according to the anodization treatment described above. The film thickness when anodization is performed in a boric acid aqueous solution containing a sodium borate is preferably at least 100 nm, more preferably at least 300 nm. The upper limit is the film thickness of the porous anodized film. As a result, it can be used in a substrate of thin-film solar cells, in which high-temperature strength is a requirement and flexibility is a plus.

A preferred chemical method that can be used is to make a structure in which pores and/or voids are filled with a silicon oxide substance after anodization treatment. Filling with a silicon oxide substance may be performed by coating with a solution containing a compound having Si—O bonds, or by immersing for 1-30 seconds in sodium silicate aqueous solution (aqueous solution containing 1-5 mass % No. 1 sodium silicate or No. 3 sodium silicate, at 20-70° C.) and then washing with water, drying, and firing for 1-60 minutes at 200-600° C.

A preferred chemical method other than the above-described sodium silicate aqueous solution is to perform pore sealing treatment by immersing for 1-60 seconds at 20-70° C. in a solution having a concentration of 1-5 mass % containing sodium fluorosilicate and/or sodium dihydrogen phosphate alone or a mixture with a mixing ratio of 5:1 to 1:5 by weight.

Anodization treatment can be performed using, for example, a known so-called roll-to-roll process anodization apparatus.

Next, after anodization treatment, the protective sheet (not shown) is peeled off. Then, the substrate body 15 on which an insulation layer 18 was formed on the front surface 14a of the aluminum base 14 is thermally oxidized at a temperature of 150-600° C., for example. As a result, as shown in FIG. 5D, an oxide film 16 is formed with a thickness of at least 6 nm, for example, on the back surface 12b of the steel base 12. At this time, an alloy layer 20 is produced with a thickness of 0.01-10 μm at the interface between the steel base 12 and aluminum base 14.

The thermal oxidation treatment for forming the oxide film 16 is performed, for example, in an oxygen-containing atmosphere, carbon dioxide-containing atmosphere, water vapor-containing atmosphere or theoretical air atmosphere.

When thermal oxidation treatment is performed at 450° C. for at least 10 minutes, the thickness of the formed oxide film 16 is a thick 25 μm, for example. For this reason, the preferred thermal oxidation conditions are a temperature of 450° C. for at least 10 minutes. However, the thermal oxidation treatment for forming the oxide film 16 must be performed under the temperature and time conditions under which the alloy 20 is produced, such conditions being determined as shown in FIGS. 2A and 2B. For this reason, the thermal oxidation treatment conditions for forming the oxide film 16 are preferably set such that the alloy layer 20 is 0.01-10 μm, preferably 0.01-5 μm, considering the heat treatment conditions that result in an alloy layer 20 of thickness 10 μm as shown in FIGS. 2A and 2B.

Note that in this embodiment, when a long substrate 10 is produced, using the so-called roll-to-roll process, the aluminum base 14 can be formed while the steel base 12 is conveyed in the lengthwise direction, and the insulation layer 18 and oxide film 16 can be formed while the substrate body 15 is conveyed in the longitudinal direction.

Also, in the production method of the substrate 10 of this embodiment, after the anodized film is formed, the oxide film 16 and alloy layer 20 are formed by thermal oxidation treatment. For this reason, even if a wet process is used in forming the anodized film and the surface or interior of the anodized film contains moisture, the amount of moisture in the anodized film can be reduced because thermal oxidation treatment is performed at the time of formation of the oxide film 16 and alloy layer 20. As a result, the amount of evaporation of moisture from the anodized film can be reduced and deterioration of the degree of vacuum can be suppressed when depositing films on the substrate 10 in a vacuum atmosphere.

Also, the substrate 10 of this embodiment is utilized in the substrate of solar cells, photoelectric conversion elements and so forth comprising a selenium compound semiconductor produced using selenium. Since the oxide film 16 is provided in order to prevent reaction between selenium and the steel base 12, formation of the oxide film 16 is performed at a point prior to the process in which selenium is used. Also, since the oxide film 16 is formed by heat treatment, it is preferred that it is formed after the insulation layer 18 is formed, as described above. In this way, it is preferred that the oxide film 16 is formed at a point after formation of the insulation layer 18 and prior to the process in which selenium is used.

Also, the timing of formation of the alloy layer 20 may be simultaneous with the oxide film 16, or after formation of the oxide film 16, for example, when the photoelectric conversion layers are formed.

Next, a second embodiment of the invention will be described.

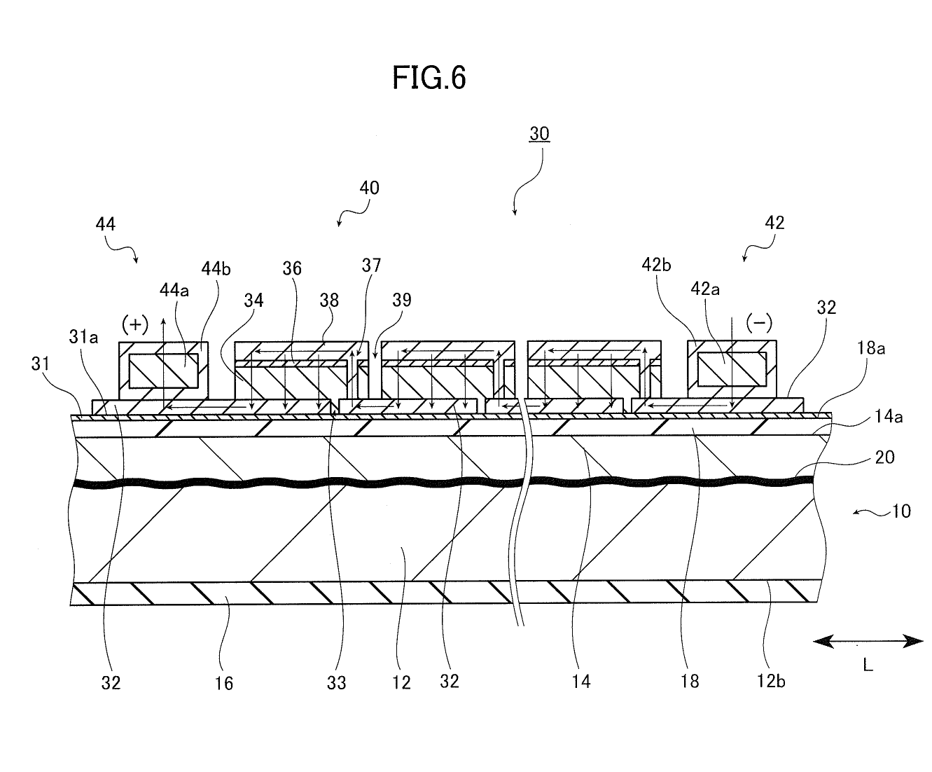

FIG. 6 is a cross-sectional diagram schematically illustrating a solar cell submodule provided in a thin-film solar cell module according to a second embodiment of the present invention.

Note that in this embodiment, the same components as those of the substrate 10 according to the first embodiment illustrated in FIG. 1 will be given the same reference numerals, and a detailed description thereof will be omitted.

The thin-film solar module of this embodiment uses the substrate 10 of the first embodiment as the substrate, and solar cell submodules 30 are formed on this substrate 10.

The solar cell submodule 30 has a plurality of photoelectric conversion elements 40 (integrated device), a first conductive member 42 and a second conductive member 44.

The photoelectric conversion elements 40 function as solar cells, and are constructed from, for example, a soda lime glass layer 31, back electrode 32, photoelectric conversion layers 34, buffer layer 36 and transparent electrode 38.

The soda lime glass layer 31 is formed on the front surface 18a of the insulation layer 18. On the front surface 31a of the soda lime glass layer 31, the back electrode 32, photoelectric conversion layer 34, buffer layer 36 and transparent electrode 38 are laminated in sequence.

The back electrodes 32 are formed on the front surface 31a of the soda lime glass layer 31, with separation grooves (P1) 33 provided for separation from adjacent back electrodes 32. The photoelectric conversion layer 34 is formed on the back electrodes 32 so as to fill the separation grooves (P1) 33. The buffer layer 36 is formed on the front surface of the photoelectric conversion layer 34. The photoelectric conversion layers 34 and the buffer layers 36 are separated from adjacent photoelectric conversion layers 34 and adjacent buffer layers 36 by grooves (P2) 37 which reach the back electrodes 32. The grooves (P2) 37 are formed in different positions from those of the separation grooves (P1) 33 that separate the back electrodes 32. In the photoelectric conversion elements 40, the back electrode 32 is formed in a predetermined pattern by the separation grooves (P1) 33, and the photoelectric conversion layer 34 is formed in a predetermined pattern by the grooves (P2) 37.

The transparent electrode 38 is formed on the surface of the buffer layer 36 so as to fill the grooves (P2) 37.

Opening grooves (P3) 39 are formed so as to reach the back electrodes 32 by penetrating through the transparent electrode 38, the buffer layer 36, and the photoelectric conversion layer 34. The photoelectric conversion elements 40 are connected in series in the longitudinal direction L of the substrate 10 via the back electrodes 32 and the transparent electrodes 38.

The photoelectric conversion elements 40 of this embodiment are so-called integrated photoelectric conversion elements (solar cells), and have a configuration such that, for example, the back electrode 32 is a molybdenum electrode, the photoelectric conversion layer 34 is formed of a selenium semiconductor compound produced using selenium such as CIS, CIGS or the like, the buffer layer 36 is formed of CdS, and the transparent electrode 38 is formed of ZnO.

Note that the photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 6, the first conductive member 42 is connected to the rightmost back electrode 32. The first conductive member 42 is provided to collect the output from a negative electrode to be described later. Although a photoelectric conversion element 40 is formed on the rightmost back electrode 32, that photoelectric conversion element 40 is removed by, say, laser scribing or mechanical scribing to expose the back electrode 32.

The first conductive member 42 is, for example, a member in the shape of an elongated strip which extends substantially linearly in the width direction of the substrate 10 and is connected to the rightmost back electrode 32. As shown in FIG. 6, the first conductive member 42 has, for example, a copper ribbon 42a covered with a coating material 42b made of an alloy of indium and copper. The first conductive member 42 is connected to the back electrode 32 by, for example, ultrasonic soldering.

A second conductive member 44 is provided to collect the output from the positive electrode to be described later. Like the first conductive member 42, the second conductive member 44 is a long strip extending substantially linearly in the width direction of the substrate 10, connected to the leftmost back electrode 32. Although a photoelectric conversion element 40 is formed on the leftmost back electrode 32, that photoelectric conversion element 40 is removed by, say, laser scribing or mechanical scribing to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-plated copper ribbon. Furthermore, the method of connection of the first conductive member 42 and the second conductive member 44 is not limited to ultrasonic soldering, and they may be connected by such means as, for example, a conductive adhesive or conductive tape.

The photoelectric conversion elements 40 of this embodiment may be produced by any known methods used to produce GIGS solar cells which use selenium.

The separation grooves (P1) 33 of the back electrodes 32, the grooves (P2) 37 reaching the back electrodes 32, and the opening grooves (P3) 39 reaching the back electrodes 32 may be formed by laser scribing or mechanical scribing.

In the solar cell submodule 30, light impinging on the photoelectric conversion elements 40 from the side bearing the transparent electrodes 38 passes through the transparent electrodes 38 and the buffer layers 36 and causes the photoelectric conversion layers 34 to generate electromotive force, thus producing a current that flows, for example, from the transparent electrodes 38 to the back electrodes 32. Note that the arrows shown in FIG. 6 indicate the direction of the current, and the direction in which electrons move is opposite to that of current. Therefore, in the photoelectric converters 48, the leftmost back electrode 32 in FIG. 6 has a positive polarity (plus polarity) and the rightmost back electrode 32 has a negative polarity (minus polarity).

In this embodiment, electric power(electromotive force) generated in the solar cell submodule 30 can be output from the solar cell submodule 30 through the first conductive member 42 and the second conductive member 44.

Also, in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the solar cell submodule 30, and the like.

In this embodiment, the photoelectric conversion elements 40 are formed so as to be connected in series in the longitudinal direction L of the substrate 10 through the back electrodes 32 and the transparent electrodes 38, but the present invention is not limited thereto. For example, the photoelectric conversion elements 40 may be formed so as to be connected in series in the width direction through the back electrodes 32 and the transparent electrodes 38.

The back electrodes 32 and the transparent electrodes 38 of the photoelectric conversion elements 40 are both provided to collect current generated by the photoelectric conversion layers 34. Both the back electrodes 32 and the transparent electrodes 38 are each made of a conductive material. The transparent electrodes 38 must be have translucency.

The soda lime glass layer 31 is for diffusing an alkali metal element, for example, Na in the photoelectric conversion layer 34 (CIGS layer). This is because it has been reported that photoelectric conversion efficiency is increased when an alkali metal element, for example, Na is diffused in the photoelectric conversion layer 34 (CIGS layer). In the photoelectric conversion elements 40, an alkali metal can be diffused in the photoelectric conversion layer 34 (CIGS layer) and photoelectric conversion efficiency can be increased by providing a soda lime glass layer 31.

In this embodiment, it is not limited to a soda lime glass layer 31, provided that it can diffuse an alkali metal element in the photoelectric conversion layer 34 (CIGS layer).

For example, a layer containing an alkali metal element may be formed by vapor deposition or sputtering on top of the back electrodes 32. Or, an alkali layer composed of Na₂S or the like may be formed on the back electrode by dipping, for example. Also, a layer may be formed on the back electrodes 32 by forming a precursor containing indium(In), copper(Cu) and gallium metal(Ga) elements, and then applying an aqueous solution containing sodium molybdate, for example, to the precursor.

Instead of the soda lime glass layer 31, a layer containing one or two or more alkali metal compounds such as Na₂S, Na₂Se, NaCl, NaF and sodium molybdate salt may be provided inside the back electrodes 32.

Note that the solar cell submodule 30 of this embodiment may also be configured such that the back electrodes 32 are formed on the front surface 18a of the insulation layer 18, rather than a soda lime glass layer 31 being provided.

The back electrodes 32 are formed, for example, of molybdenum(Mo), chromium(Cr) or tungsten(W), or a combination thereof. The back electrodes 32 may have a single-layer structure or a laminated structure such as a two-layer structure. The back electrodes 32 have a thickness of 100 nm or more, preferably 0.45-1.0 μm.

The back electrodes 32 may be formed by any vapor-phase film deposition method such as electron beam vapor deposition or sputtering.

The transparent electrodes 38 are formed, for example, of ZnO doped with aluminum(Al), boron(B), gallium(Ga), antimony(sb), etc., ITO (indium tin oxide), SnO₂, or a combination thereof. The transparent electrodes 38 may have a single-layer structure or a laminated structure such as a two-layer structure. The thickness of the transparent electrodes 38, which is not specifically limited, is preferably 0.3-1 μm.

The method of forming the transparent electrodes 38 is not particularly limited; they may be formed by coating techniques or vapor-phase deposition techniques such as electron beam vapor deposition and sputtering.

The buffer layers 36 are provided to protect the photoelectric conversion layers 34 when forming the transparent electrodes 38 and to allow the light impinging on the transparent electrodes 38 to enter the photoelectric conversion layers 34.

The buffer layers 36 are made of, for example, CdS, ZnS, ZnO, ZnMgO or ZnS (O, OH) or a combination thereof.

The buffer layers 36 preferably have a thickness of 0.03-1 μm. The buffer layers 36 are formed by, for example, chemical bath deposition (CBD) method.

The photoelectric conversion layer 34 has a photoelectric conversion function, such that it generates current by absorbing light that has reached it through the transparent electrode 38 and the buffer layer 36. In this embodiment, the photoelectric conversion layer 34 contains selenium or a selenium semiconductor compound produced using selenium. Examples of the photoelectric conversion layer 34 include CuAlSe₂, CuGaSe₂, CuInSe₂ (CIS), AgAlSe₂, AgGaSe₂, AgInSe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂ and Ag(In₁₋ₓGa) (S, Se)₂.

The photoelectric conversion layers 34 preferably contain CuInSe₂(CIS) and/or Cu(In, Ga)Se₂ (GIGS), which is obtained by solid-dissolving Ga in the former. CIS and GIGS are semiconductors each having a chalcopyrite crystal structure, and reportedly have high optical absorbance and high photoelectric conversion efficiency. Further, they have little deterioration of efficiency under exposure to light and exhibit excellent durability.

The photoelectric conversion layer 34 contains impurities for obtaining the desired semiconductor conductivity type. Impurities may be added to the photoelectric conversion layer 34 by diffusion from adjacent layers and/or direct doping into the photoelectric conversion layer 34. There may be a concentration distribution of constituent elements of group semiconductors and/or impurities in the photoelectric conversion layer 34, which may contain a plurality of layer regions formed of materials having different semiconductor properties such as n-type, p-type, and i-type.

For example, in a GIGS semiconductor, when provided with a distribution in the amount of gallium in the direction of thickness in the photoelectric conversion layer 34, the band gap width, carrier mobility, etc. can be controlled, and thus high photoelectric conversion efficiency is achieved.

When the photoelectric conversion layer 34 of this embodiment is a GIGS layer, the GIGS layer may be formed by such known film deposition methods as 1) multi-source co-evaporation method, 2) selenization method, 3) sputtering method, 4) hybrid sputtering method, and 5) mechanochemical processing method.

1) Known multi-source co-evaporation methods include: the three-stage method (J. R. Tuttle et al., Mat. Res. Soc. Symp. Proc., Vol. 426 (1966), p. 143, etc.), and the co-evaporation method by EC group (L. Stolt et al.: Proc. 13th ECPVSEC (1995, Nice), 1451, etc.).

According to the former three-phase method, firstly, indium(In), gallium(Ga) and selenium(Se) are simultaneously vapor-deposited under high vacuum at a substrate temperature of 300° C., which is then increased to 500° C. to 560° C. to simultaneously vapor-deposit copper and selenium, whereupon indium(In), gallium(Ga) and selenium(Se) are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:
a) Method using ionized gallium (H. Miyazaki et al., Phys. Stat. Sol. (a), Vol. 203 (2006), p. 2603, etc.);
b) Method using cracked selenium (a pre-printed collection of presentations given at the 68th Academic Lecture by the Japan Society of Applied Physics) (autumn, 2007, Hokkaido Institute of Technology), 7P-L-6, etc.)
c) Method using radicalized selenium (a pre-printed collection of presentations given at the 54th Academic Lecture by the Japan Society of Applied Physics) (spring, 2007, Aoyama Gakuin Univ.), 29P-ZW-10, etc.); and
d) Method using a light excitation process (a pre-printed collection of presentations given at the 54th Academic Lecture by the Japan Society of Applied Physics) (spring, 2007, Aoyama Gakuin Univ.), 29P-ZW-14, etc.).

2) The selenization method is also called the two-stage method, whereby, firstly, a metal precursor formed of a laminated film such as a copper layer/indium layer, a (copper-gallium) layer/indium layer or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

The selenization method may be implemented in several ways: selenium is previously mixed in a given ratio into the metal precursor film to avoid abrupt volume expansion that might take place in the selenization process (T. Nakada et al., Solar Energy Materials and Solar Cells 35 (1994), 204-214, etc.); or selenium is sandwiched between thin metal films (e.g., as in copper layer/indium layer/selenium layer . . . copper layer/indium layer/selenium layer) to form a multiple-layer precursor film (T. Nakada et al., Proc. of 10th European Photovoltaic Solar Energy Conference (1991), 887-890, etc.).

An exemplary method of forming a graded band gap CIGS film is a method which involves first depositing a copper-gallium (Cu—Ga) alloy film, depositing an indium film thereon and selenizing with a gallium concentration gradient in the film thickness direction making use of natural thermal diffusion (K. Kushiya et al., Tech. Digest 9th Photovoltaic Science and Engineering Conf. Miyazaki, 1996 (Intn. PVSEC-9, Tokyo, 1996), p. 149,etc.).

3) Known sputtering techniques include: a technique using CuInSe₂ polycrystal as a target, a technique two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and, a technique called three-source sputtering whereby a copper target, an indium target and a selenium or CuSe target are sputtered in argon gas (T. Nakada et al., Jpn. J. Appl. Phys. 32 (1993), L1169-L1172, etc.).

4) Exemplary known methods for hybrid sputtering include one in which copper and indium metals are subjected to DC sputtering in the sputtering method described above, while only selenium is vapor-deposited (T. Nakada et al., Jpn. Appl. Phys. 34 (1995), 4715-4721, etc.).

5) An exemplary method for mechanochemical processing includes a method in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming CIGS films include screen printing, close-spaced sublimation, MOCVD and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine-particle film to pyrolysis treatment (which may be a pyrolysis treatment carried out under a group VIb element atmosphere) (JP 09-74065 A, JP 09-74213 A, etc.).

Next, the method of producing the solar cell submodule 30 according to this embodiment will be described.

First, the substrate 10 is prepared. The method of producing the substrate 10 is the same as in the first embodiment, and therefore a detailed description thereof is omitted.

Then, a soda lime glass layer 31 is formed on the front surface 18a of the insulation layer 18 of the substrate 10 by sputtering using a film deposition apparatus.

Then, a molybdenum film serving as the back electrodes 32 is formed on the front surface 31a of the soda lime glass layer 31 by sputtering using a film deposition apparatus.

Then, for example, laser scribing is used to scribe the molybdenum film at a first predetermined position to form the separation grooves (P1) 33 extending in the width direction of the substrate 10. The back electrodes 32 separated from each other by the separation grooves (P1) 33 are thus formed.

Then, for example, a CIGS layer serving as a photoelectric conversion layer 34 (p-type semiconductor layer) is formed by any of the film deposition methods described above using a film deposition apparatus, so as to cover the back electrodes 32 and to fill in the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Then, laser scribing is used to scribe a second position, which differs from the first position of the separation grooves (P1) 33, so as to form grooves (P2) 37 which extend in the width direction of the substrate 10 and reach the back electrodes 32.

Then, a layer of ZnO doped with, for example, aluminum, boron, gallium, antimony or the like which serves as the transparent electrodes 38 is formed on the buffer layer 36 by sputtering or coating using a film deposition apparatus so as to fill the grooves (P2) 37.

Then, laser scribing is used to scribe a third position, which differs from the first position of the separation grooves (P1) 33 and the second position of the grooves (P2) 37, so as to form opening grooves (P3) 39 which extend in the width direction of the substrate 10 and reach the back electrodes 32.

Then, the photoelectric conversion elements 40 formed on the rightmost and leftmost back electrodes 32 in the longitudinal direction L of the substrate 10 are removed by, for example, laser scribing or mechanical scribing, to expose the back electrodes 32. Then, the first conductive member 42 and the second conductive member 44 are connected by, for example, ultrasonic soldering onto the rightmost and leftmost back electrodes 32, respectively.

The solar cell submodule 30 in which a plurality of photoelectric conversion elements 40 are electrically connected in series can be thus produced, as shown in FIG. 6.

Then, a bond/seal layer (not shown), a water vapor barrier layer (not shown) and a surface protection layer (not shown) are arranged on the front side of the resulting solar cell submodule 30, and a bond/seal layer (not shown) and a back sheet (not shown) are formed on the back side of the solar cell submodule 30, that is, on the back side of the substrate 10, and these layers are integrated by vacuum lamination, for example. A thin-film solar cell module is thus obtained.

In this embodiment, the substrate 10 is flexible as described above. For this reason, the soda lime glass layer 31, back electrode 32, photoelectric conversion layer 34 (GIGS layer), buffer layer 36 (CdS layer) and transparent electrode 38 of the solar cell submodule 30 may also be formed using the roll-to-roll process while the substrate 10 is moved for example along the longitudinal direction L. Thus, manufacturing costs of the solar cell submodule 30 can be reduced because the solar cell submodule 30 is produced using the inexpensive roll-to-roll process. As a result, the cost of a thin-film solar cell module can be reduced.

In this embodiment, it is acceptable if at least the back electrode 32 is formed using the roll-to-roll process.

Also, if the photoelectric conversion layer 34 (GIGS layer) is formed using the roll-to-roll process, the back surface of the substrate 10 and the front surface of the photoelectric conversion layer 34 contact each other during winding. In this case, if iron particles are wrapped into the photoelectric conversion layer 34, the iron will diffuse inside the photoelectric conversion layer 34 and reduce the photoelectric conversion efficiency of the photoelectric conversion layer 34. However, since an oxide film 16 is formed on the back surface of the substrate 10, generation of iron particles is suppressed, and a reduction in photoelectric conversion efficiency of the photoelectric conversion layer 34 by this incorporation of iron particles can be prevented.

In this embodiment, insulation characteristics are excellent and corrosion of the steel base 12 is prevented because the substrate 10 is used and an insulation layer 18 is formed. Moreover, heat resistance of the substrate 10 is excellent. Thus, a solar cell submodule 30 with excellent durability and storage life can be obtained. For this reason, the thin-film solar cell module also has excellent durability and storage life.

In this embodiment, an oxide film 16 is formed on the back surface 12b of the steel base 12 on the substrate 10. For this reason, corrosion of the substrate 10 by selenium which is used when forming the CIGS layer as the photoelectric conversion layer 34 can be suppressed, and a reduction in strength of the substrate 10 can be suppressed. Additionally, since corrosion can be suppressed, formation of iron-selenium compounds by corrosion of the steel base 12 by selenium is also suppressed. Furthermore, contamination caused by iron-selenium compounds turning into dust and flying around inside the processing chamber is prevented. Thus, a CIGS layer as a photoelectric conversion layer 34 can be formed with good stability.

It is preferred that the CIGS layer that constitutes the photoelectric conversion layer 34 is formed at a temperature of at least 500° C., because conversion efficiency is better when it is formed at high temperature. Thus, in the production process of the solar cell submodule 30, the alloy layer 20 can be generated at the interface between the steel base 12 and the aluminum base 14 of the substrate 10 when the photoelectric conversion layer 34 is formed.

For this reason, the film deposition conditions of the photoelectric conversion layer 34 may be set such that the alloy layer 20 is 0.01-10 μm, preferably 0.01-5 μm, considering the heat treatment conditions that result in an alloy layer 20 of thickness 10 μm as shown in FIG. 2A described above, and considering the thermal oxidation conditions for forming the oxide film 16 by thermal oxidation.

Also, in the substrate 10, the amount of contained moisture can be reduced even if the insulation layer 18 is an anodized film formed by a wet process, because the oxide film 16 is formed by thermal oxidation after formation of the insulation layer 18. For this reason, in cases where the soda lime glass layer 31 is formed by sputtering, a reduction in the degree of vacuum due to the moisture content of the substrate 10 can be suppressed. Thus, throughput can be improved.

The present invention is basically as described above. The substrate for selenium compound semiconductors, the production method of a substrate for selenium compound semiconductors and the thin-film solar cell of the present invention have been described above in detail, but the present invention is by no means limited to the above embodiments, and various improvements or design modifications may be made without departing from the scope and spirit of the present invention.

### EXAMPLE 1

Example 1 of the substrate for selenium compound semiconductors of the present invention will be specifically described below.

In this embodiment, the object produced as follows was used as experimental example No. 1. In experimental example No. 1, the substrate body used was constructed of an aluminum base of purity 4N formed on a steel base of SUS430 ferritic stainless steel. The thickness of the steel base was 100 μm, and the thickness of the aluminum base was 30 μm. The substrate body was formed by pressurizing and bonding of the aluminum base to the steel base.

A protective sheet was pasted onto the rear surface and side surfaces of the steel base so that the steel base did not directly contact the solution. After that, the substrate body was immersed together with an aluminum opposing electrode into a solution of 0.1M oxalic acid adjusted to temperature 16° C., and then DC voltage of 40 V was applied for 1 hour, causing anodization of the aluminum base of the substrate body, and an anodized film of thickness approximately 10 μm was thereby formed as an insulation layer.

Then, the substrate body on which the anodized film had been formed was washed with pure water and the protective sheet was removed, and then it was additionally washed in acetone and then ethanol, and the components of the adhesive of the protective sheet were thereby removed.

Then, the substrate body on which the insulation layer had been formed was submitted to thermal oxidation treatment in a heating furnace for 1 hour at 300° C. in a dry air atmosphere. A substrate on which an oxide film of thickness 6 μm was formed on the back surface of a steel base was thus obtained.

Note that the thickness of the oxide film was determined by Auger electron spectroscopy as described above.

Then, on the front surface of the insulation layer of the substrate, a soda lime glass layer was formed at a thickness of 200 nm by sputtering.

Then, on the surface of the soda lime glass layer, a molybdenum film of thickness 500 nm was formed as the back electrodes.

Then, on the front surface of the molybdenum film, a CIGS layer was formed at a thickness of 1.5-2.5 μm as a photoelectric conversion layer using a multisource vapor deposition apparatus at 520° C., by simultaneous vapor deposition of copper and selenium, followed by simultaneous vapor deposition of indium, gallium and selenium.

In doing so, experimental example No. 1 was obtained, composed of a soda lime glass layer, molybdenum film and CIGS layer laminated in that order on an oxide film of a substrate.

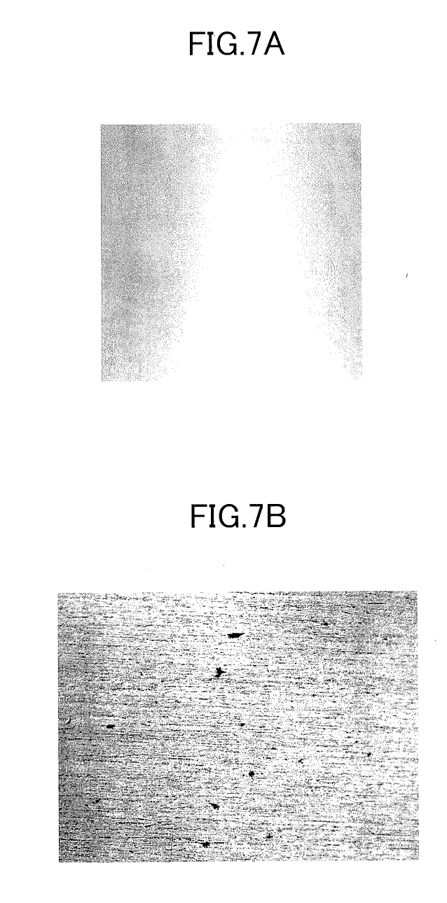

Then, the back surface of the substrate after CIGS layer formation of experimental example No. 1 was objectively visually observed and was observed by microscope (200× magnification). The results are shown in FIGS. 7A and 7B.

As shown in FIG. 7A, there was nothing seen attached to the back surface of the substrate in objective visual observation. Also, in observation by microscope, as shown in FIG. 7B, there was no evidence that selenium reacted with the back surface of the substrate.

Thus, in experimental example No. 1, even if selenium vapor surrounds the back side of the substrate during CIGS layer formation, corrosion of the steel base by selenium is prevented because an oxide film was formed. For this reason, generation of iron-selenium compounds by selenium can be prevented, and additionally, generation of dust of iron-selenium compounds can also be prevented.

The object produced as follows was used as experimental example No. 2. In experimental example No. 2, similar to experimental example No. 1 above, a substrate body on which an insulation layer had been formed was submitted to thermal oxidation treatment in a heating furnace for 10 minutes at 450° C. in a dry air atmosphere. A substrate on which an oxide film of thickness 25 μm had been formed on the back surface of a steel base was thus obtained. On this substrate, a soda lime glass layer, molybdenum film and CIGS layer were formed under the same conditions as experimental example No. 1, thus producing experimental example No. 2.

Then, similar to experimental example No. 1, the back surface of the substrate after CIGS layer formation of experimental example No. 2 was objectively visually observed and was observed by microscope (200× magnification). In experimental example No. 2, there was nothing seen attached to the back surface of the substrate in objective visual observation. Also, in observation by microscope, there was no evidence that selenium reacted with the back surface of the substrate.

The object produced as follows was used as experimental example No. 3. In experimental example No. 3, similar to experimental example No. 1 above, a substrate body on which an insulation layer had been formed was submitted to thermal oxidation treatment in a heating furnace for 30 minutes at 450° C. in a dry air atmosphere. A substrate on which an oxide film of thickness 31 μm had been formed on the back surface of a steel base was thus obtained. On this substrate, a soda lime glass layer, molybdenum film and CIGS layer were formed under the same conditions as experimental example No. 1, thus producing experimental example No. 3.

Then, similar to experimental example No. 1, the back surface of the substrate after CIGS layer formation of experimental example No. 3 was objectively visually observed and was observed by microscope (200× magnification). In experimental example No. 3, there was nothing seen attached to the back surface of the substrate in objective visual observation. Also, in observation by microscope, there was no evidence that selenium reacted with the back surface of the substrate.

The object produced as follows was used as experimental example No. 4. In experimental example No. 4, similar to experimental example No. 1 above, a substrate body on which an insulation layer had been formed was submitted to thermal oxidation treatment in a heating furnace for 60 minutes at 450° C. in a dry air atmosphere. A substrate on which an oxide film of thickness 35 μm had been formed on the back surface of a steel base was thus obtained. On this substrate, a soda lime glass layer, molybdenum film and CIGS layer were formed under the same conditions as experimental example No. 1, thus producing experimental example No. 4.

Then, similar to experimental example No. 1, the back surface of the substrate after CIGS layer formation of experimental example No. 4 was objectively visually observed and was observed by microscope (200× magnification). In experimental example No. 4, there was nothing seen attached to the back surface of the substrate in objective visual observation. Also, in observation by microscope (200× magnification), there was no evidence that selenium reacted with the back surface of the substrate.

As described above, in experimental example Nos. 2-4, even if selenium vapor surrounds the back side of the substrate during CIGS layer formation, corrosion of the steel base by selenium is prevented because an oxide film was formed. For this reason, generation of iron-selenium compounds by selenium can be prevented, and additionally, generation of dust of iron-selenium compounds can also be prevented. Note that in experimental example No. 1, selenium compounds were generated on very rare occasion, but in experimental example Nos. 2-4, there was no generation of selenium compounds.

The object produced as follows was used as experimental example No. 10. In experimental example No. 10, the substrate used was one on which an oxide film was not formed, by omission of the thermal oxidation process using a heating furnace on the substrate body on which an insulation layer had been formed under the same conditions as experimental example No. 1 above. On this substrate, a soda lime glass layer, molybdenum film and CIGS layer were formed under the same conditions as experimental example No. 1, thus producing experimental example No. 10.

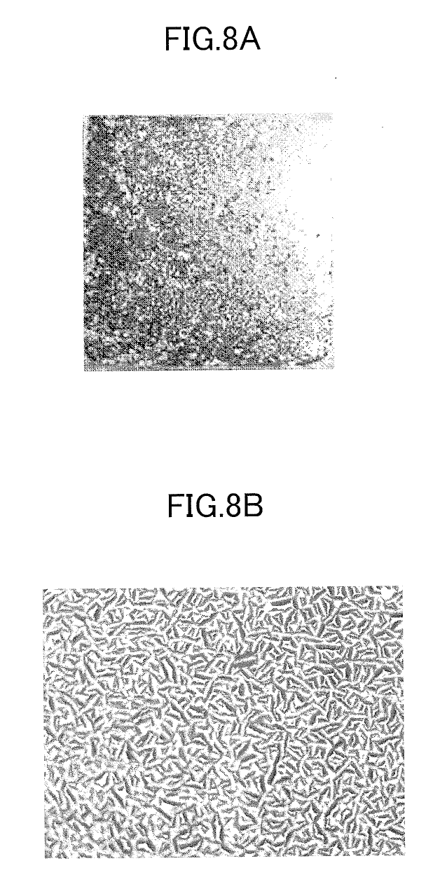

The back surface of the substrate after CIGS layer formation of experimental example No. 10 was objectively visually observed and was observed by microscope (200× magnification). The results are shown in FIGS. 8A and 8B.

As shown in FIG. 8A, a large amount of powder of iron-selenium compounds was seen on the back surface of the substrate in objective visual observation. Also, in observation by microscope, as shown in FIG. 8B, there was evidence that selenium reacted with the back surface of the substrate.

Note that after formation of the CIGS layer, an oxide film was formed on the back surface of the steel base. The thickness of this oxide film, similar to experimental example No. 1, was 5 pm as determined by Auger electron spectroscopy.

Also, because the anodized film has a porous structure, a large amount of moisture remains adsorbed after film deposition. For this reason, it is difficult to maintain vacuum in the sputtering process when the soda lime glass layer is formed.

However, in experimental example No. 1, the amount of adsorbed moisture was reduced as a result of introducing the thermal oxidation process, and the degree of vacuum did not deteriorate in the soda lime glass layer formation process. For this reason, in experimental example No. 1, each process proceeded without any wait time to reach vacuum. Thus, throughput was improved.

On the other hand, in experimental example No. 10, the degree of vacuum deteriorated in the soda lime glass layer formation process, and it took time to reach vacuum, and therefore throughput could not be improved.

### EXAMPLE 2

In this example 2, the same substrate body as experimental example No. 1 was used, except that the steel base was austenitic stainless steel of thickness 100 μm, which differs from experimental example No. 1 of example 1 above. An oxide film was formed on this substrate body under the same conditions as experimental example No. 1. On the oxide film, a soda lime glass layer, molybdenum film and CIGS layer were laminated in that order under the same conditions as experimental example No. 1, thus producing experimental example No. 11.

The back surface of the substrate after CIGS layer formation of experimental example No. 11 was objectively visually observed and was observed by microscope (200× magnification). As a result, similar to experimental example No. 1, there was nothing seen attached to the back surface of the substrate in objective visual observation, and there was no evidence that selenium reacted with the back surface of the substrate in observation by microscope.

As experimental example No. 12, the same substrate body as experimental example No. 1 was used, except that the steel base was austenitic stainless steel of thickness 100 μm, which differs from experimental example No. 1 of example 1 above. On this substrate body, without an oxide film being formed, a soda lime glass layer, molybdenum film and CIGS layer were laminated in that order under the same conditions as experimental example No. 1.

The back surface of the substrate after CIGS layer formation of experimental example No. 12 was objectively visually observed and was observed by microscope (200× magnification). As a result, similar to experimental example No. 10, a large amount of powder of iron-selenium compounds was seen on the back surface of the substrate in objective visual observation, and there was evidence that selenium reacted with the back surface of the substrate in observation by microscope.

Also, as described above, because the anodized film has a porous structure, a large amount of moisture remains adsorbed after film deposition. For this reason, it is difficult to maintain vacuum in the soda lime glass layer formation process. However, in experimental example No. 11, the amount of adsorbed moisture was reduced by a thermal oxidation process being introduced, and the degree of vacuum did not deteriorate. As a result, in experimental example No. 11, each process proceeded without any wait time to reach vacuum. Thus, throughput was improved.

On the other hand, in experimental example No. 12, the degree of vacuum deteriorated in the soda lime glass layer formation process, and it took time to reach vacuum, and therefore throughput could not be improved.

### EXAMPLE 3

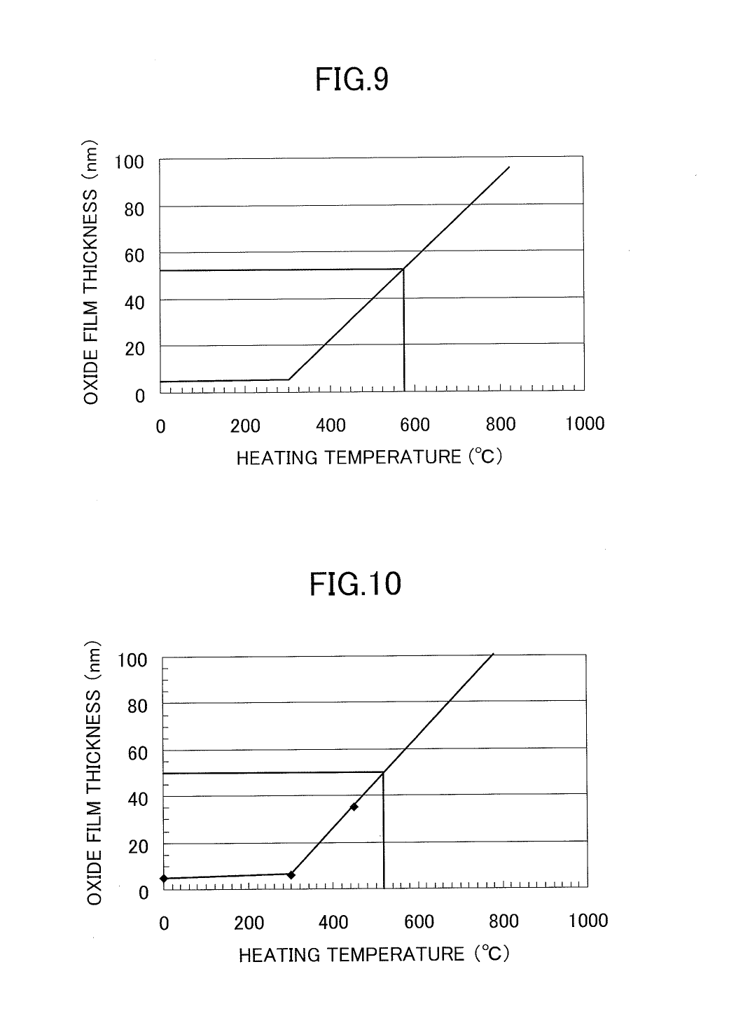

In this example 3, thermal oxidation treatment was performed on sample A and sample B shown below while varying the heating temperature. The thickness of the oxide film and the thickness of the alloy layer formed at each temperature in sample A and sample B on which thermal oxidation treatment was performed were measured, and cross-sections of the samples were observed. The oxide film thickness results at each temperature are shown in FIG. 9 and FIG. 10.

Note that the thickness of the oxide film was determined by Auger electron spectroscopy, similar to experimental example No. 1 described above. Also, the thermal oxidation treatment was performed in a theoretical air atmosphere (N₂ gas:O₂ gas=4:1).

Observation and alloy layer thickness measurement of samples A and B after thermal oxidation treatment were performed as follows.

First, samples A and B after thermal oxidation treatment were sectioned by a diamond cutter, after which figuring was performed by ion polishing using an argon ion beam. Then, the cross-sections of samples A and B after thermal oxidation treatment were observed by SEM-EDX (scanning electron microscope with energy-dispersive X-ray spectroscope). Because the average electron quantities of the steel base 12, aluminum base 14, oxide film 16, insulation layer 18 and alloy layer 20 are different, an image with distinct contrasts is obtained when an SEM-reflected electron image is used. The area of each layer in the image was measured by image analysis, and the thickness of the alloy layer 20 was determined by dividing it by the length of the field of observation. The observed field magnification was set to 1000-10,000 in accordance with the thickness of the alloy layer 20 that had grown.

### Sample A

A commercially available ferritic stainless steel (SUS430) and high-purity aluminum (aluminum purity: 4N) were joined by cold rolling to prepare a two-layer clad material containing an aluminum base 14 with a thickness of 30 μm and a steel base 12 (stainless steel) with a thickness of 50 μm.

The base surface and end surfaces were covered with a masking film, after which it was ultrasonically cleaned in an ethanol solution, and electrolytically polished with a solution of acetic acid and perchloric acid. After that, an insulation layer 16 (anodized film of aluminum) was formed at a thickness of 10 μm by constant-voltage electrolysis of 40 volt in an 80 g/L oxalic acid solution. Note that the thickness of the aluminum base 14 after insulation layer formation was 20 μm.

### Sample B

A commercially available low-carbon steel (SPCC) and high-purity aluminum (aluminum purity: 4N) were joined by cold rolling to prepare a two-layer clad material containing an aluminum base 14 with a thickness of 30 μm and a steel base 12 (low-carbon steel) with a thickness of 50 μm. On this two-layer clad material, an insulation layer 16 was formed by the same treatment as sample A. Note that the thickness of the aluminum base 14 after insulation layer formation was 20 μm.

In samples A and B, cracking was seen when the alloy layer exceeded 10 μm.

In sample A, as shown in FIG. 9, the alloy layer was too thick and peeling occurred unless the oxide film thickness was 52 nm or less under thermal oxidation conditions of a heating time of 10 minutes and a temperature of 575° C. That is, in sample A, the tolerable thickness of the oxide film such that the alloy layer does not exceed 10 μm is 52 nm.

In sample B, the alloy layer was too thick and peeling occurred unless the oxide film thickness was 50 nm or less under thermal oxidation conditions of a heating time of 1 minutes and a temperature of 530° C. That is, in sample B, the tolerable thickness of the oxide film such that the alloy layer does not exceed 10 μm is 50 nm.

What is claimed is:

1. A substrate for selenium compound semiconductor, comprising: at least a steel base; and an aluminum base,
wherein said aluminum base is arranged on one end in a direction of lamination of said steel base and said aluminum base, said steel base is arranged on the other end in the direction of lamination, and
wherein an alloy layer having a thickness of from 0.01 μm to 10 μm is formed between said steel base and said aluminum base, and
wherein a thermal oxide film having a thickness of 6 nm or more is formed on a surface of said steel base opposite to said aluminum base.

2. The substrate for selenium compound semiconductor according to claim 1, wherein an insulation layer made of alumina is formed on a surface of said aluminum base opposite to said steel base.

3. The substrate for selenium compound semiconductor according to claim 2, wherein said insulation layer comprises an anodized film formed by anodizing a material of said aluminum base made of aluminum.

4. The substrate for selenium compound semiconductor according to claim 2, wherein said steel base, said aluminum base, said thermal oxide film and said insulation layer are flexible.

5. The substrate for selenium compound semiconductor according to claim 1, wherein said thermal oxide film contains Fe₂O₃, Fe₃O₄ and Cr₂O₃.

6. The substrate for selenium compound semiconductor according to claim 1, wherein said thermal oxide film is an iron-based oxide film containing Fe₃O₄ as a principal component.

7. The substrate for selenium compound semiconductor according to claim 1, wherein said thermal oxide film has a thickness of at least 25 nm.

8. A production method of a substrate for selenium compound semiconductor on which treatment using selenium is performed, comprising the steps of:
forming a substrate body in which at least a steel base and an aluminum base are laminated such that said aluminum base is arranged on one end in a direction of lamination and said steel base is arranged on the other end in the direction of lamination; and,
performing thermal oxidation treatment on said substrate body to form a thermal oxide film having a thickness of 6 nm or more on a surface of said steel base opposite to said aluminum base, as well as to form an alloy layer having a thickness of from 0.01 μm to 10 μm between said steel base and said aluminum base.

9. The production method of a substrate for selenium compound semiconductor according to claim 8, further comprising a step of forming an insulation layer made of alumina on the surface of said aluminum base opposite to said steel base.

10. The production method of a substrate for selenium compound semiconductor according to claim 9, wherein said thermal oxidation treatment is performed after said step of forming said insulation layer and before said treatment using selenium.

11. The production method of a substrate for selenium compound semiconductor according to claim 9, wherein said insulation layer is formed by anodization treatment.

12. The production method of a substrate for selenium compound semiconductor according to claim 8, wherein said thermal oxide film is formed at a temperature of from 150° C. to 600° C.

13. The production method of a substrate for selenium compound semiconductor according to claim 8, wherein said thermal oxide film is formed in an atmosphere containing oxygen, an atmosphere containing carbon dioxide gas, or an atmosphere containing water vapor.

14. The production method of a substrate for selenium compound semiconductor according to claim 8, wherein said steel base comprises ferritic stainless steel or austenitic stainless steel.

15. A thin-film solar cell, comprising:
the substrate for selenium compound semiconductor according to claim 1; and
photoelectric conversion layers formed on said substrate,
wherein said photoelectric conversion layers are selenium compound semiconductor formed by evaporating at least selenium.

16. A thin-film solar cell, comprising:
the substrate for selenium compound semiconductor according to claim 2; and
films laminated on said insulation layer of said substrate and constituting said selenium compound semiconductor,
wherein said films comprises: at least
a back electrode made of molybdenum and formed on said insulation layer of said substrate; and
a photoelectric conversion layer made of CIGS and formed on said back electrode.

17. The production method of a substrate for selenium compound semiconductor according to claim 16, wherein at least said back electrode is formed by using a roll-to-roll process.

18. The thin-film solar cell according to claim 16, wherein an integrated device comprises said back electrode formed in a predetermined pattern and said photoelectric conversion layer formed in a predetermined pattern.

19. The thin-film solar cell according to claim 16, further comprising a soda lime glass layer formed between said insulation layer of said substrate and said back electrode.
